(19) United States
(12) Patent Application Publication
(10) Pub. No.: US 2008/0278219 A1
(43) Pub. Date: Nov. 13, 2008

(54) BIAS SWITCHING CIRCUIT

(75) Inventor: Duk-Min LEE, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/116,154

(22) Filed: May 6, 2008

(30) Foreign Application Priority Data
May 9, 2007 (KR) 2007-0045097

(51) Int. Cl. H03K 3/01; G11C 5/14

(52) U.S. Cl. 327/534; 327/530

(57) ABSTRACT

An embodiment of a bias switching circuit may include a first transfer switch that transmits a bias voltage to a first output node in response to a first switching signal, a second transfer switch that transmits a first power voltage to the first output node in response to a second switching signal, a third transfer switch that transmits the bias voltage to a second output node in response to the second switching signal, a fourth transfer switch that transmits the first power voltage to the second output node in response to the first switching signal. The circuit may further include a first transistor that transmits a second power voltage to the first output node in response to a third switching signal, and a second transistor that transmits the second power voltage to the second output node in response to a fourth switching signal.

### CROSS-REFERENCE TO RELATED PATENT APPLICATIONS

This application claims the benefit of Korean Patent Application No. 10-2007-0045097, filed on May 9, 2007, in the Korean Intellectual Property Office, the disclosure of which is incorporated herein in its entirety by reference.

### BACKGROUND OF THE INVENTION

1. Field of the Invention

The present invention relates to a bias providing apparatus for generating a bias chopping voltage, and more particularly, to a bias generating circuit and a bias switching circuit capable of stably supplying a bias chopping voltage by eliminating problems caused by loading effects.

2. Description of the Related Art

Amplifiers are used in various types of electronic/electric devices such as display panel drivers. An amplifier receives an input data voltage which it amplifies to generate an output data voltage. However, the output data voltage inevitably contains a component caused by the offset characteristics of the amplifier. Thus, in a field requiring precise amplification, a chopping amplifier is used so as to remove such an offset component.

FIG. 1 is a block diagram of a chopping amplifier 140. FIG. 1 illustrates the chopping amplifier 140, and a bias providing apparatus 110 that applies first and second bias chopping voltages VBa and VBb to the chopping amplifier 140. As illustrated in FIG. 1, the bias providing apparatus 110 includes a bias generation circuit 120 and a bias switching circuit 130.

The bias voltage VB generated by the bias generation circuit 120 is applied to the bias switching circuit 130. Then, the bias switching circuit 130 generates the first and second bias chopping voltages VBa and VBb from the bias voltage VB. The first and second bias chopping voltages VBa and VBb are applied to the chopping amplifier 140. In a chopping unit 150 included in the chopping amplifier 140 an internal signal path is chopped in response to the first and second bias chopping voltages VBa and VBb in order to amplify input data voltage Vin to output data voltage Vout. For example, if the first bias chopping voltage Vba is activated, paths T1-T3 and T2-T4 are formed, and if the second bias chopping voltage VBb is activated, paths T1-T4 and T2-T3 are formed. Accordingly, it is possible to prevent the output data voltage Vout from being influenced by an offset component by chopping the internal signal path in the chopping amplifier 140.

FIG. 2 illustrates a case where a bias providing apparatus 210 drives a plurality of chopping amplifiers 240_1, 240_2, . . . , 240_{—}n.

In a Liquid Crystal Display (LCD) panel driver, one bias providing apparatus, e.g., the bias providing apparatus 210, applies bias chopping voltages VB1a, VB1b, VB2a, and VB2b to a plurality of chopping amplifiers, e.g., the chopping amplifiers 240_1, 240_2, . . . , 240_{—}n. The bias chopping voltages VB1a and VB1b may be used to chop a path of first internal signals within the chopping amplifiers 240_1, 240_2, . . . , 240_{—}n. The bias chopping voltages VB2a and VB2b may be used to chop a path of second internal signals within the chopping amplifiers 240_1, 240_2, 240_{—}n.

However, the load capacitance of each of the chopping amplifiers 240_1, 240_2, . . . , 240_{—}n that are connected in parallel is relatively large, and thus, the whole load capacitance of the chopping amplifiers 240_1, 240_2, . . . , 240_{—}n is significantly large as compared to the driving capabilities of the bias providing apparatus 210. Thus, when the bias providing apparatus 210 having low driving capabilities applies a bias chopping voltage to the chopping amplifiers 240_1, 240_2, . . . , 240_{—}n having large load capacitance, the bias chopping voltage may be distorted due to the loading effect caused by the chopping amplifiers 240_1, 240_2, . . . , 240_{—}n that are connected in parallel. If the distorted bias chopping voltage is applied to the chopping amplifiers 240_1, 240_2, . . . , 240_{—}n, they cannot normally perform amplification.

### SUMMARY OF THE INVENTION

According to one aspect of the present invention, there is provided a bias switching circuit comprising a first transfer switch to transmit a bias voltage to a first output node in response to a first switching signal; a second transfer switch to transmit a first power voltage to the first output node in response to a second switching signal; a third transfer switch to transmit the bias voltage to a second output node in response to the second switching signal; a fourth transfer switch to transmit the first power voltage to the second output node in response to the first switching signal; a first transistor to transmit a second power voltage to the first output node in response to a third switching signal; and a second transistor to transmit the second power voltage to the second output node in response to a fourth switching signal.

Operating periods of the bias switching circuit may include a period in which the first switching signal is activated; a non-overlap period in which both the first and second switching signals are deactivated; and a period in which the second switching signal is activated. The period in which the first switching signal is activated, the non-overlap period, the period in which the second switching signal is activated, and another one of the non-overlap period, may be periodically repeated.

All the first through fourth transfer switches are turned off during the non-overlap period. The third and fourth switching signals are activated during the non-overlap period. During the non-overlap period, the first transistor may transmit the second power voltage to the first output node and the second transistor may transmit the second power voltage to the second output node. The bias voltage, the second power voltage, the first voltage and the second power voltage may be sequentially output from the first output node. The first power voltage, the second power voltage, the bias voltage and the second power voltage may be sequentially output from the second output node.

In some embodiments, the first power voltage may be a reference voltage, and the second power voltage may be a power source voltage. In other embodiments, the first power voltage may be a power source voltage, and the second power voltage may be a reference voltage.

According to another aspect of the present invention, there is provided a bias providing apparatus which provides a first bias chopping voltage that repeatedly switches between a bias voltage and a first power voltage and a second bias chopping voltage that repeatedly switches between the first power voltage and the bias voltage, the apparatus comprising a bias generation circuit generating the bias voltage; and a bias switching circuit receiving the bias voltage, the first power voltage and a second power voltage, and then outputting the first bias chopping voltage and the second bias chopping voltage. The first bias chopping voltage is a voltage signal in which the bias voltage, the second power voltage, the first power voltage and the second power voltage are periodically repeated, and the second bias chopping voltage is a voltage signal in which the first power voltage, the second power voltage, the bias voltage and the second power voltage are periodically repeated.

### BRIEF DESCRIPTION OF THE DRAWINGS

The above and other features and advantages of the present invention will become more apparent by describing in detail exemplary embodiments thereof with reference to the attached drawings in which:

FIG. 1 is a block diagram of a chopping amplifier;

FIG. 2 illustrates a case where a bias providing apparatus drives a plurality of chopping amplifiers;

FIG. 3A is a circuit diagram of a bias generation circuit included in a bias providing apparatus;

FIGS. 3B and 3C are circuit diagrams of examples of a bias switching circuit included in a bias providing apparatus;

FIG. 3D is a timing diagram of a switching signal and an inverted switching signal applied to the bias switching circuit illustrated in FIG. 3B or 3C;

FIG. 3E is a graph illustrating a bias chopping voltage that is distorted when a plurality of chopping amplifiers are driven by a bias providing apparatus that includes the bias generation circuit of FIG. 3A and the bias switching circuit of FIG. 3C;

FIG. 4A is a circuit diagram of a bias switching circuit according to an embodiment of the present invention;

FIG. 4B is a circuit diagram of a bias switching circuit according to another embodiment of the present invention;

FIG. 5A is a timing diagram of switching signals applied to the bias switching circuit of FIG. 4A and the bias switching circuit of FIG. 4B;

FIG. 5B is a circuit diagram of a switching signal supplier that supplies switching signals to the bias switching circuit of FIG. 4A or 4B, according to an embodiment of the present invention; and

FIG. 6 is a graph illustrating bias chopping voltages when a plurality of chopping amplifiers are driven by a bias providing apparatus having the bias generation circuit of FIG. 3A and the bias switching circuit of FIG. 4B, according to an embodiment of the present invention.

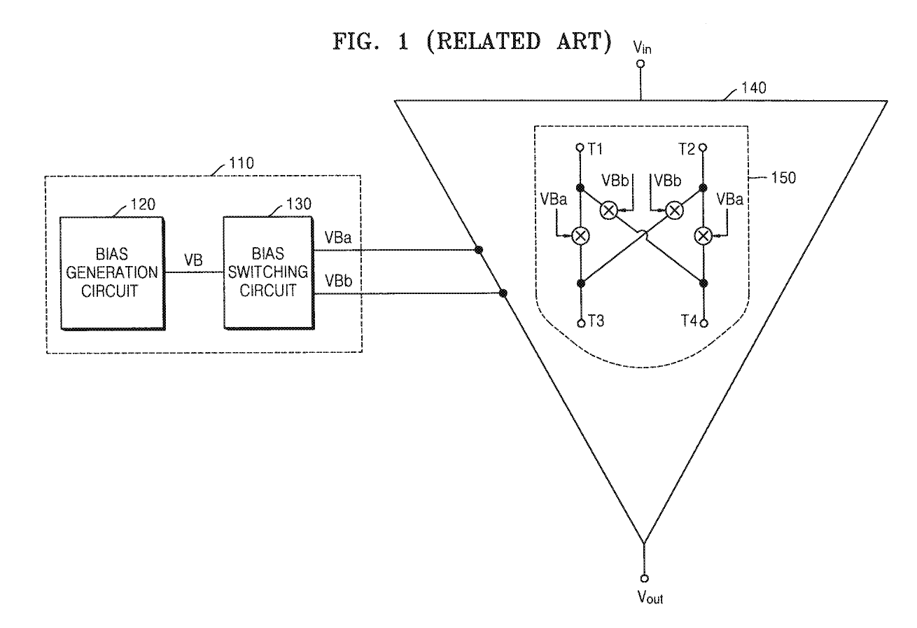

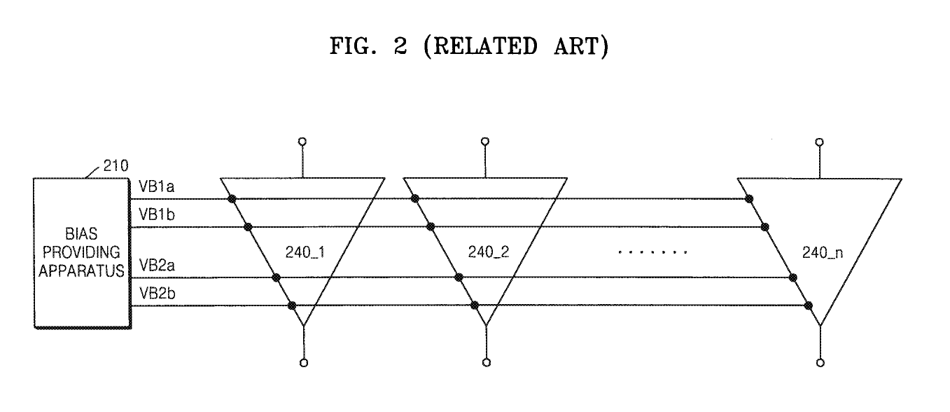

### DETAILED DESCRIPTION OF THE INVENTION

Exemplary embodiments of the present invention will now be described more fully with reference to the accompanying drawings. In the following description, well-known functions or constructions are not described in detail if it is determined that they would obscure the invention due to unnecessary detail.

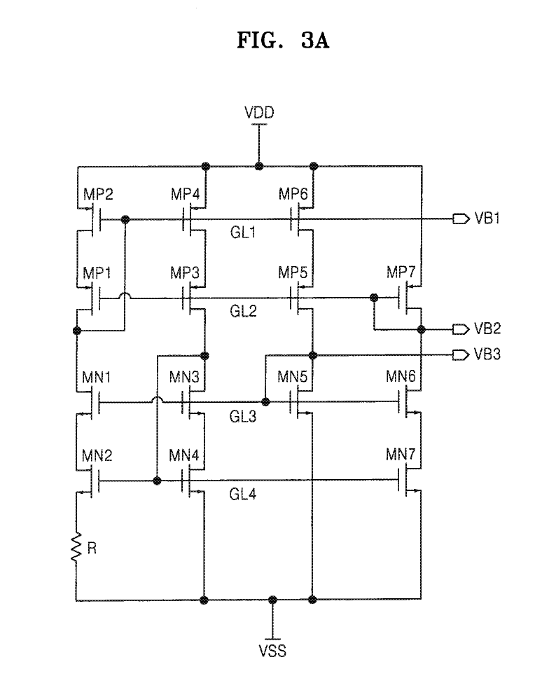

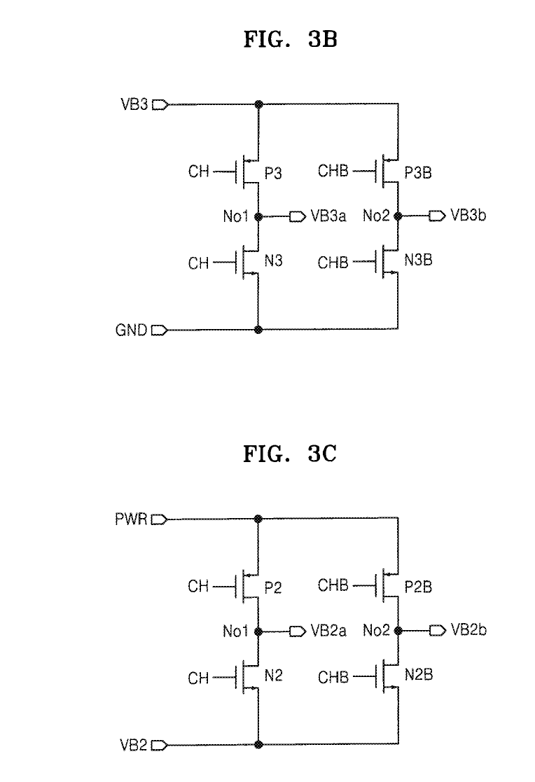

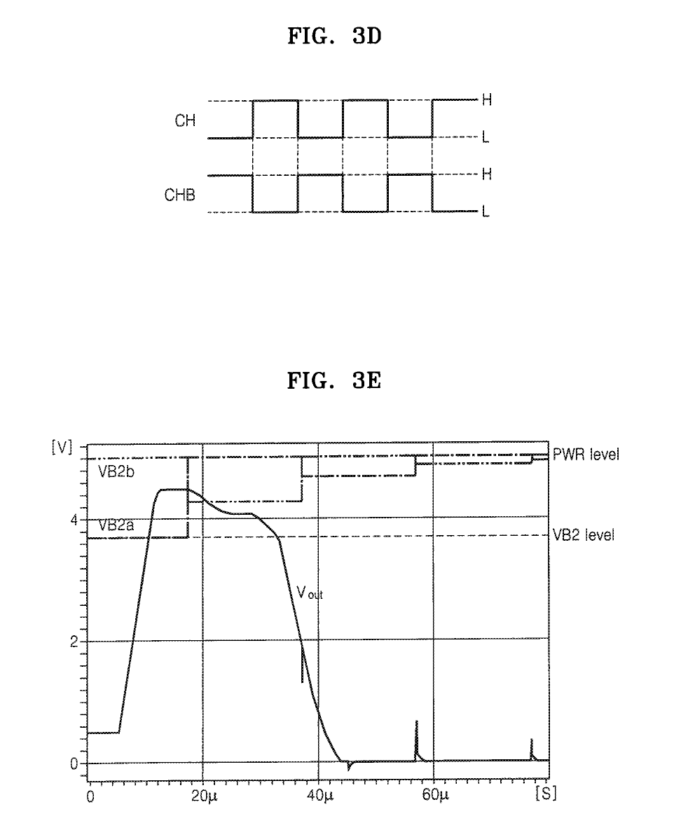

First, a bias providing apparatus will be described in greater detail with reference to FIGS. 3A through 3E.

FIG. 3A is a circuit diagram of a bias generation circuit included in a bias providing apparatus, according to an embodiment of the present invention. Referring to FIG. 3A, the bias generation circuit includes a first path (MP2, MP1, MN1, MN2, R), a second path (MP4, MP3, MN3, MN4), a third path (MP6, MP5, MN5), and a fourth path (MP7, MN6, MN7) that are formed between a first power voltage source VDD and a second power voltage VSS; and first through fourth gate lines GL1 through GL4.

A first bias voltage VB1 is output via the first gate line GL1, a second bias voltage VB2 is output via the second gate line GL2, and a third bias voltage VB3 is output via the third gate line GL3.

FIGS. 3B and 3C are circuit diagrams of a bias switching circuit included in a bias providing apparatus, according to embodiments of the present invention. FIG. 3D is a timing diagram of a switching signal CH and an inverted switching signal CHB supplied to the bias switching circuit illustrated in FIG. 3B or 3C.

For example, the bias switching circuit illustrated in FIG. 3B receives a third bias voltage VB3 and a first power voltage which is a reference voltage GND, and outputs a bias chopping voltage VB3a and a bias chopping voltage VB3b. During a time period where a switching signal CH is at logic low (L) and an inverted switching signal CHB is at logic high (H), a transistor P3 and a transistor N3B are turned on and a transistor N3 and a transistor P3B are turned off. Thus, the third bias voltage VB3 is output via a first output node No1 and the reference voltage GND is output via a second output node No2. In a period where the switching signal CH is at logic high (H) and the inverted switching signal CHB is at logic low (L), the transistor N3 and the transistor P3B are turned on and the transistor P3 and the transistor N3B are turned off. Thus, the reference voltage GND is output via the first output node No1 and the third bias voltage VB3 is output via the second output node No2.

As this process is repeatedly performed, the third bias voltage VB3a that repeatedly switches between the third bias voltage VB3 and the reference voltage GND is output via the first output node No1. Similarly, the bias chopping voltage VB3b that repeatedly switches between the reference voltage GND and the third bias voltage VB3 is output via the second output node No2.

Also, the bias switching circuit illustrated in FIG. 3C receives a second bias voltage VB2 and a second power voltage which is a power source voltage PWR, and outputs a bias chopping voltage VB2a and a bias chopping voltage VB2b. In a period where a switching signal CH is at logic low (L) and an inverted switching signal CHB is at logic high (H), a transistor P2 and a transistor N2B are turned on and a transistor N2 and a transistor P2B are turned off. Thus, the power voltage PWR is output via a first output node No1 and the second bias voltage VB2 is output via a second output node No2. In a period where the switching signal CH is at logic high (H) and the inverted switching signal CHB is at logic low (L), the transistor N2 and the transistor P2B are turned on and the transistor P2 and the transistor N2B are turned off. Thus, the second bias voltage VB2 is output via the first output node No1 and the power voltage PWR is output via the second output node No2.

As this process is repeatedly performed, the bias chopping voltage VB2a that repeatedly switches between the power voltage PWR and the second bias voltage VB2 is output via the first output node No1. Similarly, the bias chopping voltage VB2b that repeatedly switches between the second bias voltage VB2 and the power voltage PWR is output via the second output node No2.

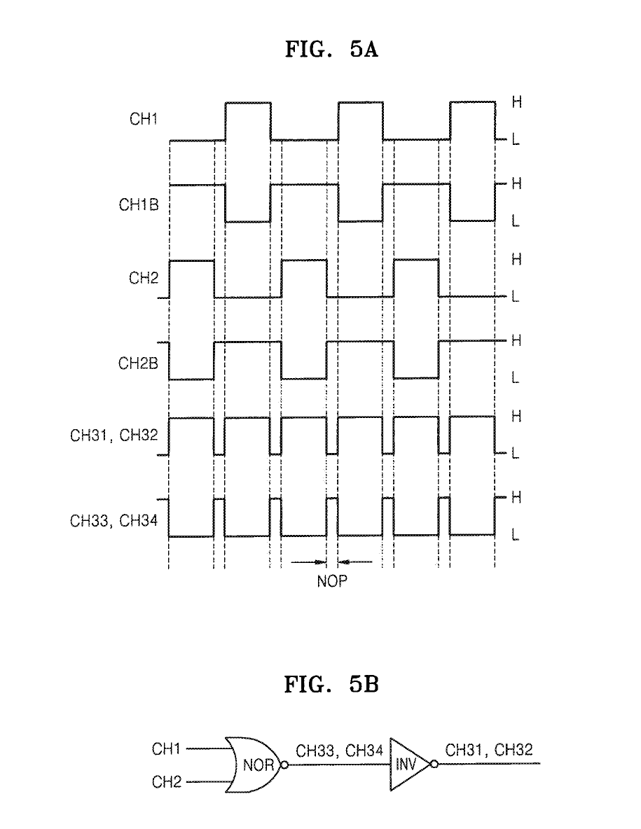

However, if a switching signal CH and an inverted switching signal CHB illustrated in FIG. 3D are supplied to the bias switching circuit illustrated in FIG. 3B or 3C, the edge timing of the switching signal CH occurs at a similar time to the edge timing of the switching signal CHB as illustrated in FIG. 3D. Thus, an unstable state where both the transistor P3 and the transistor N3 or both the transistor P3B and the transistor N3B are turned off may occur. In such an unstable state, an abnormal bias chopping voltage will be output. Accordingly, according to one aspect of the present invention, a non-overlap period (NOP) is introduced in order to remove the possibility of such an unstable state occurring. The NOP will be described in greater detail with reference to FIG. 5A.

FIG. 3E is a graph illustrating a bias chopping voltage that is distorted when a plurality of chopping amplifiers are driven by a bias providing apparatus having the bias generation circuit illustrated in FIG. 3A and the bias switching circuit illustrated in FIG. 3C. In FIG. 3E, the x-axis denotes a time [S] and the y-axis denotes a voltage [V].

If the bias providing apparatus does not drive a plurality of chopping amplifiers, that is, if the chopping amplifiers are not connected to the first output node No1 illustrated in FIG. 3C, a normal bias chopping voltage VB2a that repeatedly switches between a second bias voltage VB2 and a power voltage PWR is output from the first output node No1. However, if the bias providing apparatus drives the chopping amplifiers, that is, if the chopping amplifiers are connected to the first output node No1, a distorted bias chopping voltage VB2a as illustrated in FIG. 3E is output from the first output node No1.

Referring to FIG. 3E, the bias chopping voltage VB2a rises to a power voltage PWR but does not fall to a second bias voltage VB2. The more the signal transition is repeated, the more the bias chopping voltage converges on the power voltage PWR. The reason why the bias chopping voltage VB2a converges on the power voltage PWR when the chopping amplifiers are connected to the first output node No1 will be described.

Each of the chopping amplifiers may be modeled as an equivalent circuit that consists of a load resistor and a load capacitor. Thus, if the power voltage PWR is output from the first output node No1, the chopping amplifiers are charged with the power voltage PWR, and if the second bias voltage VB2 is output from the first output node No1, the chopping amplifiers are charged with the second bias voltage VB2. However, a source illustrated in FIG. 3C that applies the power voltage PWR has a driving capability for sufficiently applying the power voltage PWR to the chopping amplifiers, while a source illustrated in FIG. 3C (the bias generation circuit illustrated in FIG. 3A) that applies the second bias voltage VB2 does not have a driving capability for sufficiently applying the second bias voltage VB2 to the chopping amplifiers. For this reason, once the chopping amplifiers are given the power voltage PWR from the first output node No1 and are charged with the power voltage PWR, they cannot be charged with the second bias voltage VB2 even if the second bias voltage VB2 from the first output node No1 is applied to the chopping amplifiers. This is because the loading effect caused by the chopping amplifiers being charged with the power voltage PWR prevents the operation of the source (the bias generation circuit illustrated in FIG. 3A) that applies the second bias voltage VB2.

Some of the inventive principles have been described above with respect to the bias chopping voltage VB2a, and the bias chopping voltage VB2b is similar to the case of the bias chopping voltage VB2a as illustrated in FIG. 3E. Thus, when the distorted bias chopping voltages VB2a and VB2b are applied to the chopping amplifiers, the chopping amplifiers cannot perform normal amplification due to the loading effects. For example, even if input data voltage Vin that alternates high and low is applied to a chopping amplifier, an output data voltage Vout illustrated in FIG. 3E that does not alternate high and low, is output from the chopping amplifier, That is, an output data voltage Vout irrespective of the input data voltage Vin is output from the chopping amplifier. Accordingly, the present invention is designed to solve the problems cause by the loading effect.

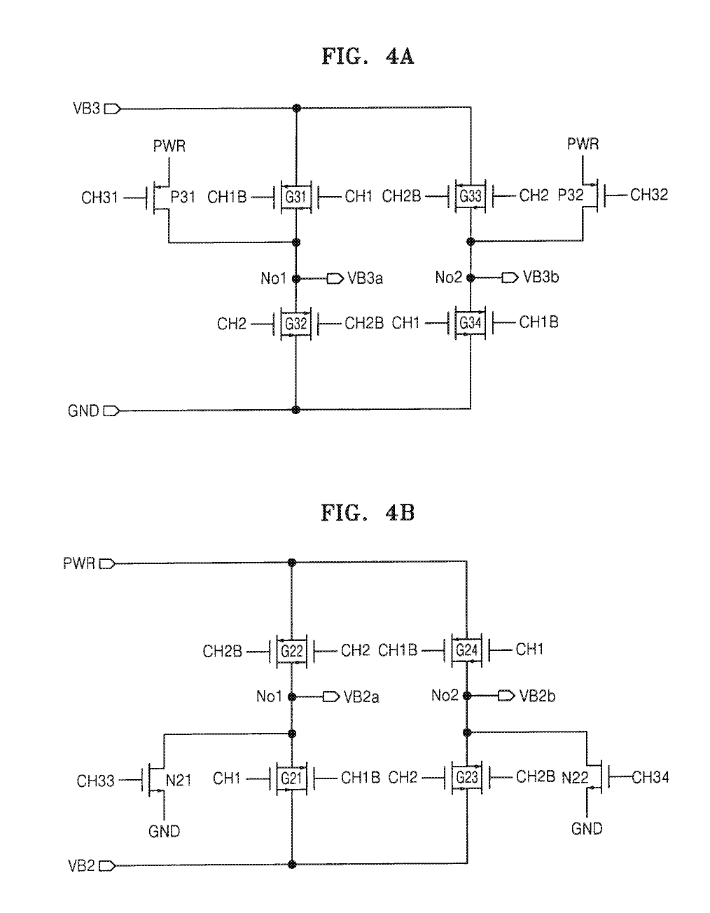

FIG. 4A is a circuit diagram of a bias switching circuit according to an embodiment of the present invention. FIG. 4B is a circuit diagram of a bias switching circuit according to another embodiment of the present invention. FIG. 5A is a timing diagram of switching signals CH1, CH1B, CH2, CH2B, CH31, CH32, CH33, and CH34 supplied to the bias switching circuit illustrated in FIG. 4A or 4B. The bias switching circuits illustrated in FIG. 4A and 4B will now be described with reference to FIG. 5A.

The bias switching circuit illustrated in FIG. 4A includes a first transfer switch G31, a second transfer switch G32, a third transfer switch G33, a fourth transfer switch G34, a first transistor P31, and a second transistor P32. The bias switching circuit illustrated in FIG. 4A receives a bias voltage VB3, a reference voltage GND, and a power voltage PWR, and outputs a bias chopping voltage VB3a and a bias chopping voltage VB3b.

The first transfer switch G31 transmits the bias voltage VB3 to a first output node No1 in response to first switching signals CH1 and CH1B. The second transfer switch G32 transmits the reference voltage GND to the first output node No1 in response to second switching signals CH2 and CH2B. The third transfer switch G33 transmits the bias voltage VB3 to the second output node No2 in response to the second switching signals CH2 and CH2B. The fourth transfer switch G34 transmits the reference voltage GND to the second output node No2 in response to the first switching signals CH1 and CH1B. The first transistor P31 transmits the reference voltage GND to the second output node No2 in response to the third switching signal CH31. The second transistor P32 transmits the power voltage PWR to the second output node No2 in response to the fourth switching signal CH32.

As illustrated in FIG. 5A, the first switching signal CH1 and the second switching signal CH2 are alternately activated to logic “high” (H), and the first inverted switching signal CH1B and the second inverted switching signal CH2B are alternately activated to logic “low” (L). The present invention has adopted the NOP in order to prevent the first transfer switch G31 and the second transfer switch G32 from being turned on together and the third transfer switch G33 and the fourth transfer switch G34 from being turned off together. In the NOP, both the first switching signal CH1 and the second switching signal CH2 are deactivated to logic “low” (L) and both the first inverted switching signal CH1B and the second inverted switching signal CH2B are deactivated to logic “high” (H). Instead, in the NOP, the third and fourth switching signals CH31 and CH32 are activated. In the NOP, both the first through fourth transfer switches G31 through G34 are turned off, the first transistor P31 transmits the power voltage PWR to the first output node No1, and the second transistor P32 transmits the power voltage PWR to the second output node No2.

The operational periods of the bias switching circuit illustrated in FIG. 4A may be categorized, depending on whether each of the first switching signals CH1 and CH1B, the second switching signals CH2 and CH2B, the third switching signal CH31 and the fourth switching signal CH32 is activated. For example, the operational periods of the bias switching circuit of FIG. 4A include a period where the first switching signals CH1 and CH1B are activated, a NOP period (NOA) where all the first switching signals CH1 and CH1B and the second switching signals CH2 and CH2B are deactivated, and a period where the second switching signals CH2 and CH2B are activated. As illustrated in FIG. 5A, the period where the first switching signals CH1 and CH1B are activated, the NOA, the period where the second switching signals CH2 and CH2B are activated, and the NOA are periodically repeated. That is, a first period where the first switching signals CH1 and CH1B are activated, a second period NOA where the third switching signal CH31 and the fourth switching signal CH32 are activated, a third period where the second switching signals CH2 and CH2B are activated, and a fourth period NOA where the third switching signal CH31 and the fourth switching signal CH32 are activated, are periodically repeated.

In the first period where the first switching signal CH1 is activated and the second switching signal CH2 is deactivated, the first transfer switch G31 and the fourth transfer switch G34 are turned on and the second transfer switch G32 and the third transfer switch G33 are turned off. Thus, the bias voltage VB3 is output from the first output node No1, and the reference voltage GND is output from the second output node No2.

In the second period where the first switching signal CH1 and the second switching signal CH2 are deactivated and the third switching signal CH31 and the fourth switching signal CH32 are activated, the first transistor P31 and the second transistor P32 are turned on and all the first through fourth transfer switches G31 through G34 are turned off. Thus, the power voltage PWR is output from both the first output node No1 and the second output node No2.

In the third period where the first switching signal CH1 is deactivated and the second switching signal CH2 is activated, the first transfer switch G31 and the fourth transfer switch G34 are turned off and the second transfer switch G32 and the third transfer switch G33 are turned on. Therefore, the reference voltage GND is output from the first output node No1 and the bias voltage VB3 is output from the second output node No2.

In the fourth period where the first switching signal CH1 and the second switching signal CH2 are deactivated and the third switching signal CH31 and the fourth switching signal CH32 are activated, the power voltage PWR is output from both the first and second output nodes No1 and No2, similar to the second period.

As the first through fourth periods are periodically repeated, the bias voltage VB3, the power voltage PWR, the reference voltage GND, and the power voltage PWR are sequentially output from the first output node No1, and the reference voltage GND, the power voltage PWR, the bias voltage VB3, and the power voltage PWR are sequentially output from the second output node No2.

If the first and second transistors P31 and P32 are P type Metal-Oxide Semiconductor Field Effect Transistors (MOSFETs) as illustrated in FIG. 4A, the third switching signal CH31 and the fourth switching signal CH32 are activated to logic “low” (L) in the NOP as illustrated in FIG. 5A. Alternatively, if the first and second transistors are N type MOSFETs, the third switching signal and the fourth switching signal are activated to logic “high” (H) in the NOP. In this disclosure, the third switching signal CH31 and the fourth switching signal CH32 are described as different signals but may be the same signal as illustrated in FIG. 5A.

FIG. 4A illustrates all the first through fourth transfer switches G31 through G34 as Complementary Metal-Oxide Semiconductor (CMOS) type transfer gates, but the present invention is not limited thereto.

The bias switching circuit illustrated in FIG. 4B includes a first transfer switch G21, a second transfer switch G22, a third transfer switch G23, a fourth transfer switch G24, a first transistor N21, and a second transistor N22. The bias switching circuit illustrated in FIG. 4B receives a bias voltage VB2, a power voltage PWR and a reference voltage GND, and outputs a bias chopping voltage VB2a, and a bias chopping voltage VB2b.

The first transfer switch G21 transmits the bias voltage VB2 to a first output node No1 in response to the first switching signals CH1 and CH1B. The second transfer switch G22 transmits the power voltage PWR to the first output node No1 in response to second switching signals CH2 and CH2B. The third transfer switch G23 transmits the bias voltage VB2 to the second output node No2 in response to the second switching signals CH2 and CH2B. The fourth transfer switch G24 transmits the power voltage PWR to the second output node No2 in response to the first switching signals CH1 and CH1B. The first transistor N21 transmits the reference voltage GND to the first output node No1 in response to the third switching signal CH33. The second transistor N22 transmits the reference voltage GND to the second output node No2 in response to the fourth switching signal CH34.

As illustrated in FIG. 5A, in an NOP, the first switching signal CH1 and the second switching signal CH2 are deactivated to logic “low” (L), the first inverted switching signal CH1B and the second inverted switching signal CH2B are deactivated to logic “high” (H), and the third switching signal CH33 and the fourth switching signal CH34 are activated to logic “high” (H). In the NOP, all the first through fourth transfer switches G21 through G24 are turned off, the first transistor N21 transmits the reference voltage GND to the first output node No1, and the second transistor N22 transmits the reference voltage GND to the second output node No2.

The operating periods of the bias switching circuit illustrated in FIG. 4B may be divided into a period where the first switching signals CH1 and CH1B are activated, an NOA where all the first switching signals CH1 and CH1B and the second switching signals CH2 and CH2B are deactivated, and a period where the second switching signals CH2 and CH2B are activated. As illustrated in FIG. 5A, a first period where the first switching signals CH1 and CH1B are activated, a second period NOA where the third and fourth switching signals CH33 and CH34 are activated, a third period where the second switching signals CH2 and CH2B are activated, and a fourth period NOA where the third and fourth switching signals CH33 and CH34 are activated, are periodically repeated.

In the first period where the first switching signal CH1 is activated and the second switching signal CH2 is deactivated, the bias voltage VB2 is output from the first output node No1 and the power voltage PWR is output from the second output node No2. In the second period where the first and second switching signals CH1 and CH2 are deactivated and the third and fourth switching signals CH33 and CH34 are activated, the first and second transistors N21 and N22 are turned on and all the first through fourth transfer switches G21 through G24 are turned off. Thus, the reference voltage GND is output from the first output node No1 and the second output node No2. In the third period where the first switching signal CH1 is deactivated and the second switching signal CH2 is activated, the power voltage PWR is output from the first output node No1 and the bias voltage VB2 is output from the second output node No2. In the fourth period where the first and second switching signals CH1 and CH2 are deactivated and the third and fourth switching signals CH33 and CH34 are activated, the reference voltage GND is output from the first output node No1 and the second output node No2, similar to the second period.

As the first through fourth periods are periodically repeated, the bias voltage VB2, the reference voltage GND, the power voltage PWR, and the reference voltage GND are sequentially output from the first output node No1, and the power voltage PWR, the reference voltage GND, the bias voltage VB2, and the reference voltage GND are sequentially output from the second output node No2.

FIG. 5A illustrates that both the third and fourth switching signals CH33 and CH34 are activated to a logic “high” level (H), but the activation logic level of the third switching signal CH33 may change according to the type of the first transistor N21 and the activation logic level of the fourth switching signal CH34 may change according to the type of the second transistor N22. As illustrated in FIG. SA, the third and fourth switching signals CH33 and CH34 may be the same signal. FIG. 4B illustrates the first through fourth transfer switches G21 through G24 as Complementary Metal-Oxide Semiconductor (CMOS) type transfer gates, but the present invention is not limited thereto.

FIG. 5B is a circuit diagram of a switching signal supplier that supplies switching signals CH1, CH1B, CH2, CH2B, CH31, CH32, CH33, and CH34 to the bias switching circuit illustrated in FIG. 4A or 4B, according to an embodiment of the present invention.

Referring to FIG. 5B, the switching signal supplier includes a NOR gate NOR and an inverter INV. As illustrated in FIG. 5B, the third and fourth switching signals CH31 and CH32 illustrated in FIG. 4A can be generated by performing a logic OR operation on the first and second switching signals CH1 and CH2. Also, the third and fourth switching signals CH33 and CH34 illustrated in FIG. 4B can be generated by performing a logic NOR operation on the first and second switching signals CH1 and CH2.

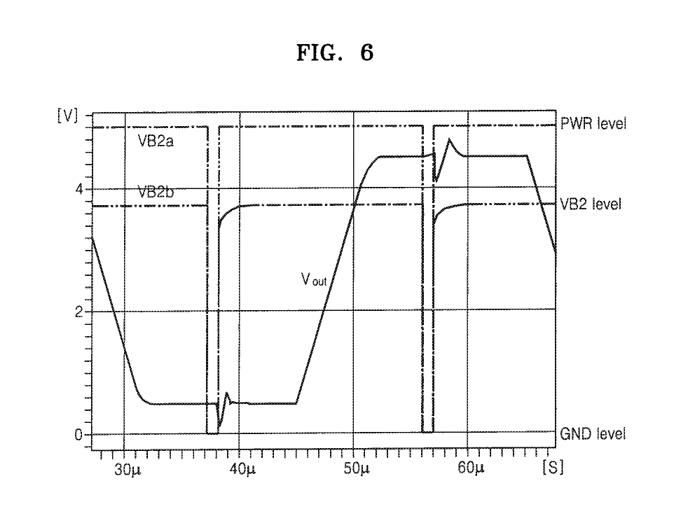

FIG. 6 is a graph illustrating bias chopping voltages VB2a and VB2b when a plurality of chopping amplifiers are driven by a bias providing apparatus having the bias generation circuit illustrated in FIG. 3A and the bias switching circuit illustrated in FIG. 4B, according to an embodiment of the present invention. In FIG. 6, the x-axis denotes a time [S] and the y-axis denotes a voltage [V].

As illustrated in FIG. 6, the bias chopping voltage VB2a output from the first output node No1 of the bias switching circuit of FIG. 4B is driven to the power voltage PWR and then becomes equal to reference voltage GND before being driven to the bias voltage VB2. Also, bias chopping voltage VB2a is driven to the bias voltage VB2 and then becomes equal to the reference voltage GND before being driven to the power voltage PWR level. That is, the bias chopping voltage VB2a is equal to the reference voltage GND in the NOP illustrated in FIG. 5A. The reason why the bias switching circuit illustrated in FIG. 4B outputs the reference voltage GND in the NOP illustrated in FIG. 5A will now be described.

As described above, in FIG. 4B, a source that supplies the power voltage PWR has the driving capabilities for sufficiently applying the power voltage PWR to a plurality of chopping amplifiers, but a source, e.g., the bias generation circuit illustrated in FIG. 3A, which supplies the bias voltage VB2 does not have the driving capabilities for sufficiently applying the bias voltage VB2 to a plurality of chopping amplifiers. Thus, the loading effect caused by the chopping amplifiers being charged with the power voltage PWR prevents the source (the bias generation circuit illustrated in FIG. 3A) from effectively applying the bias voltage VB2. In order to overcome the loading effect, according to the present invention, the source illustrated in FIG. 4B that applies the reference voltage GND causes the reference voltage GND to be applied to the first output node No1 in the NOP. The source illustrated in FIG. 4B that applies the reference voltage GND has the driving capabilities for sufficiently applying the reference voltage GND to the chopping amplifiers connected in parallel to the first output node No1 and thus can prevent the loading effect from occurring due to the chopping amplifiers charged with the power voltage PWR. Thus, the NOP can be considered as an operating period for preventing the loading effect.

Right after the NOP, that is, before the bias chopping voltage VB2a which is equal to the reference voltage GND completely increases to the bias voltage VB2, the bias chopping voltage VB2a, which is near the reference voltage GND, may be temporarily applied to the second gate line GL2 of the bias generation circuit illustrated in FIG. 3A via the first transfer switch G21 and a terminal VB2. Since all the transistors MP1, MP3, MP5, and MP7 connected to the second gate line GL2 are P type MOSFETs, they are strongly turned on when the bias chopping voltage VB2a near the reference voltage GND is applied to the second gate line GL2, thereby temporarily improving the driving capabilities of the bias generation circuit.

The present invention has been described above with respect to the bias chopping voltage VB2a output from the first output node No1 of the bias switching circuit illustrated in FIG. 4B. The case of the bias chopping voltage VB2b output from the second output node No2 of the bias switching circuit illustrated in FIG. 4B is similar to the case of the bias chopping voltage VB2a. If the bias chopping voltage VB2a and the bias chopping voltage VB2b illustrated in FIG. 6 are applied to a plurality of chopping amplifiers, the problems caused by the loading effect can be overcome and the chopping amplifiers can perform normal amplification. For example, if an input data voltage Vin that alternates high and low is applied to a chopping amplifier, an output data voltage Vout illustrated in FIG. 6 that alternates high and low (the output data voltage Vout corresponding to the input data voltage Vin) is output from the chopping amplifier.

Although FIG. 6 illustrates the bias chopping voltage VB2a and the bias chopping voltage VB2b output from the bias switching circuit illustrated in FIG. 4B, the bias chopping voltage VB3a and the bias chopping voltage VB3b output from the bias switching circuit illustrated in FIG. 4A operate in a similar manner. That is, it would be sufficiently understandable to those of ordinary skill in the art from the above description of the bias switching circuit illustrated in FIG. 4B that the source illustrated in FIG. 4A applies the power voltage PWR to the first output node No1 and the second output node No2 in the NOP in order to prevent the loading effect from occurring in the bias switching circuit illustrated in FIG. 4A, due to a plurality of chopping amplifiers charged with the reference voltage GND.

A bias providing apparatus according to the present invention may include the bias generation circuit illustrated in FIG. 3A and the bias switching circuit illustrated in FIG. 4A or 4B.

If the bias providing apparatus includes the bias generation circuit illustrated in FIG. 3A and the bias switching circuit illustrated in FIG. 4A, the bias providing apparatus is capable of supplying a plurality of chopping amplifiers with the first bias chopping voltage VB3a that alternates between the bias voltage VB3 and the reference voltage GND and the second bias chopping voltage VB3b that alternates between the reference voltage GND and the bias voltage VB3. The bias switching circuit of FIG. 4A receives the bias voltage VB3, the reference voltage GND and the power voltage PWR generated by the bias generation circuit of FIG. 3A, and then outputs the first and second bias chopping voltages VB3a and VB3b. Here, the first bias chopping voltage VB3a is a voltage signal in which the bias voltage VB3, the power voltage PWR, the reference voltage GND, and the power voltage PWR are periodically repeated, and the second bias chopping voltage VB3b is a voltage signal in which the reference voltage GND, the power voltage PWR, the bias voltage VB3, and the power voltage PWR are periodically repeated.

If the bias providing apparatus includes the bias generation circuit illustrated in FIG. 3A and the bias switching circuit illustrated in FIG. 4B, the bias providing apparatus is capable of supplying a plurality of chopping amplifiers with the first bias chopping voltage VB2a that alternates between the bias voltage VB2 and the power voltage PWR and the second bias chopping voltage VB2b that alternates between the power voltage PWR and the bias voltage VB2. The bias switching circuit illustrated in FIG. 4B receives the bias voltage VB2, the power voltage PWR, and the reference voltage GND generated by the bias generation circuit of FIG. 3A, and then outputs the first bias chopping voltage VB2a and the second bias chopping voltage VB2b. Here, the first bias chopping voltage VB2a is a voltage signal in which the bias voltage VB2, the reference voltage GND, the power voltage PWR, and the reference voltage GND are periodically repeated, and the second bias chopping voltage VB2b is a voltage signal in which the power voltage PWR, the reference voltage GND, the bias voltage VB2 and the reference voltage GND are periodically repeated.

According to the present invention, when a bias providing apparatus applies a bias chopping voltage, it is possible to prevent distortion of the bias chopping voltage by overcoming the problems caused by the loading effect.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A bias switching circuit comprising:
a first transfer switch to transmit a bias voltage to a first output node in response to a first switching signal;
a second transfer switch to transmit a first power voltage to the first output node in response to a second switching signal;
a third transfer switch to transmit the bias voltage to a second output node in response to the second switching signal;
a fourth transfer switch to transmit the first power voltage to the second output node in response to the first switching signal;
a first transistor to transmit a second power voltage to the first output node in response to a third switching signal; and
a second transistor to transmit the second power voltage to the second output node in response to a fourth switching signal.

2. The bias switching circuit of claim 1, wherein the first switching signal and the second switching signal are alternately activated.

3. The bias switching circuit of claim 1, wherein operating periods of the bias switching circuit comprise:
a period in which the first switching signal is activated;
a non-overlap period in which both the first and second switching signals are deactivated; and
a period in which the second switching signal is activated.

4. The bias switching circuit of claim 3, wherein the period in which the first switching signal is activated, the non-overlap period, the period in which the second switching signal is activated, and another one of the non-overlap period, are periodically repeated.

5. The bias switching circuit of claim 3, wherein all the first through fourth transfer switches are turned off during the non-overlap period.

6. The bias switching circuit of claim 3, wherein the third and fourth switching signals are activated during the non-overlap period.

7. The bias switching circuit of claim 6, wherein, during the non-overlap period, the first transistor transmits the second power voltage to the first output node and the second transistor transmits the second power voltage to the second output node.

8. The bias switching circuit of claim 6, wherein, if the first and second transistors are P type MOSFETs (metal-oxide semiconductor field effect transistors), the third and fourth switching signals are set to logic low during the non-overlap period.

9. The bias switching circuit of claim 6, wherein, if the first and second transistors are N type MOSFETs, the third and fourth switching signals are set to logic high during the non-overlap period.

10. The bias switching circuit of claim 1, wherein the third and fourth switching signals are the same signal.

11. The bias switching circuit of claim 10:
further comprising a switching signal supplier to supply the first through fourth switching signals, and
wherein the switching signal supplier generates the third and fourth switching signals by performing one of a logic OR operation and a logic NOR operation on the first and second switching signals.

12. The bias switching circuit of claim 1, wherein the bias voltage, the second power voltage, the first power voltage and the second power voltage are sequentially output from the first output node.

13. The bias switching circuit of claim 1, wherein the first power voltage, the second power voltage, the bias voltage and the second power voltage are sequentially output from the second output node.

14. The bias switching circuit of claim 1, wherein the first through fourth transfer switches are CMOS(Complementary Metal-Oxide Semiconductor) type transfer gates.

15. The bias switching circuit of claim 1, wherein:
the first power voltage is a reference voltage (GND); and
the second power voltage is a power source voltage (PWR).

16. The bias switching circuit of claim 1, wherein:
the first power voltage is a power source voltage (PWR); and
the second power voltage is a reference voltage (GND).

17. A bias providing apparatus to provide a first bias chopping voltage that repeatedly switches between a bias voltage and a first power voltage and a second bias chopping voltage that repeatedly switches between the first power voltage and the bias voltage, the apparatus comprising:
a bias generation circuit to generate the bias voltage; and
a bias switching circuit to receive the bias voltage, the first power voltage and a second power voltage, and output the first bias chopping voltage and the second bias chopping voltage,
wherein the first bias chopping voltage is a voltage signal in which the bias voltage, the second power voltage, the first power voltage and the second power voltage are periodically, and
wherein the second bias chopping voltage is a voltage signal in which the first power voltage, the second power voltage, the bias voltage and the second power voltage are periodically repeated.

18. The bias providing apparatus of claim 17, wherein:
the first power voltage is a reference voltage (GND); and
the second power voltage is a power source voltage (PWR).

19. A bias providing apparatus comprising:
a bias generating circuit to generate a bias signal;
a bias switching circuit to transmit a first voltage to a first output node and the bias signal to a second output node in response to a first switching signal during a first period of a bias chopping operation, and transmit the first voltage to the second output node and the bias signal to the first output node in response to a second switching signal during a second period of the bias chopping operation; and
a switching signal supplier to supply the first and second switching signals;
wherein the bias switching circuit is arranged to temporarily improve the driving capability of the bias generating circuit at a non-overlap period (NOP) between the first period and the second period.

20. The bias providing apparatus of claim 19, wherein the bias switching circuit transmits a second voltage to the first and second output nodes in response to a third switching signal during the NOP.

21. The bias providing apparatus of claim 20, wherein the first and second switching signals are both inactive during the NOP.

22. The bias providing apparatus of claim 21, wherein the switching signal supplier generates the third switching signal by performing a logic operation on the first and second switching signals.

23. The bias providing apparatus of claim 22, wherein:
the first voltage is a reference voltage (GND); and
the second voltage a power source voltage (PWR).
